(19) United States
(12) Patent Application Publication
(10) Pub. No.: US 2022/0189499 A1
(43) Pub. Date: Jun. 16, 2022

(54) VOLUME CONTROL APPARATUS, METHODS AND PROGRAMS FOR THE SAME

(71) Applicant: NIPPON TELEGRAPH AND TELEPHONE CORPORATION, Tokyo (JP)

(72) Inventors: Kazunori KOBAYASHI, Tokyo (JP); Shoichiro SAITO, Tokyo (JP); Hiroaki ITO, Tokyo (JP)

(73) Assignee: NIPPON TELEGRAPH AND TELEPHONE CORPORATION, Tokyo (JP)

(21) Appl. No.: 17/600,029

(22) PCT Filed: Mar. 23, 2020
(86) PCT No.: PCT/JP2020/012576

§ 371 Date: Sep. 29, 2021

(30) Foreign Application Priority Data
Apr. 4, 2019 (JP) 2019-071888

(51) Int. Cl. G10L 21/034; G10L 15/22; G10L 25/51

(52) U.S. Cl. CPC G10L 21/034; G10L 2015/223; G10L 25/51; G10L 15/22

(57) ABSTRACT

Provided are a volume control apparatus capable of appropriately controlling a sound volume even immediately after start of utterance, an associated method, and a program. The volume control apparatus includes a recognition unit that recognizes a predetermined voice command for use in starting voice recognition, a gain setting unit that sets a gain for an audio signal X of a target of the voice recognition, by use of an audio signal related to the predetermined voice command uttered by a user, and an adjustment unit that adjusts a sound volume of the audio signal X, by use of the gain.

### TECHNICAL FIELD

The present invention relates to a volume control apparatus that controls a sound volume of an audio signal, an associated method, and a program.

### BACKGROUND ART

As a conventional technology of volume control, Patent Literature 1 is known.

FIG. 1 shows a configuration of a volume control technology described in Patent Literature 1. A volume control apparatus of FIG. 1 includes a sound volume estimation unit 91 to which an audio signal is inputted, and that estimates a sound volume of the audio signal, a gain setting unit 92 that sets an appropriate gain value for the estimated sound volume, and a gain multiplication unit 93 that multiplies the audio signal by the set gain. Thus, the gain value is set to a value obtained by dividing an optimum sound volume by the estimated sound volume, so that sound can be controlled to an appropriate sound volume.

### CITATION LIST

### Patent Literature

Patent Literature 1: International Publication No. WO2004/071130

### SUMMARY OF THE INVENTION

### Technical Problem

In a method of Patent Literature 1, however, estimation of a sound volume requires much time. Consequently, there might be a delay in volume control, and the sound volume might be inappropriate immediately after start of utterance. Consequently, if a technology described in Patent Literature 1 is used, for example, as preprocessing to voice recognition, a problem occurs that a voice recognition ratio immediately after the start of the utterance is easy to drop.

An object of the present invention is to provide a volume control apparatus capable of appropriately controlling a sound volume even immediately after start of utterance, an associated method, and a program.

### Means for Solving the Problem

To achieve the above object, according to an aspect of the present invention, a volume control apparatus includes a recognition unit that recognizes a predetermined voice command for use in starting voice recognition, a gain setting unit that sets a gain for an audio signal X of a target of the voice recognition, by use of an audio signal related to the predetermined voice command uttered by a user, and an adjustment unit that adjusts a sound volume of the audio signal X, by use of the gain.

To achieve the above object, according to another aspect of the present invention, a volume control apparatus includes a detection unit that detects a predetermined operation to be performed in starting voice recognition, a gain setting unit that sets a gain g(n) for an n-th audio signal X(n) of a target of voice recognition of a voice uttered by a user, by use of an (n−1)-th audio signal X(n−1) of the target of the voice recognition of the voice uttered by the user, an adjustment unit that adjusts a sound volume of the audio signal X(n), by use of the gain g(n), in a case where the predetermined operation is detected, and a voice recognition unit that recognizes the voice of the audio signal X(n) having the sound volume adjusted, in the case where the predetermined operation is detected.

### Effects of the Invention

The present invention is effective in that a sound volume can be appropriately controlled even immediately after utterance. In particular, the sound volume can be controlled appropriately to perform voice recognition.

### BRIEF DESCRIPTION OF DRAWINGS

FIG. 1 is a functional block diagram of a volume control apparatus according to a conventional technology.

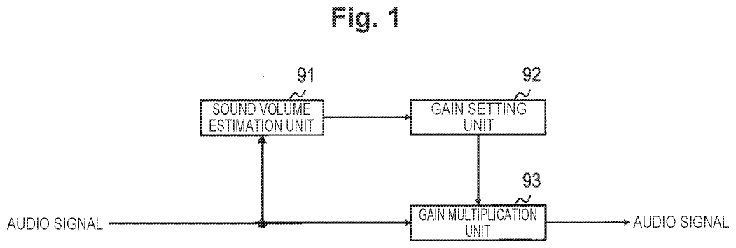

FIG. 2 is a functional block diagram of a volume control apparatus according to a first embodiment.

FIG. 3 is a diagram showing an example of a processing flow of the volume control apparatus according to the first embodiment.

FIG. 4 is a functional block diagram of a sound volume estimation unit according to the first embodiment.

FIG. 5 is a diagram for explanation of a keyword utterance time period.

FIG. 6 is a functional block diagram of a sound volume estimation unit according to a second embodiment.

FIG. 7 is a functional block diagram of a volume control apparatus according to a third embodiment.

FIG. 8 is a diagram showing an example of a processing flow of the volume control apparatus according to the third embodiment.

FIG. 9 is a functional block diagram of a sound volume estimation unit according to the third embodiment.

FIG. 10 is a diagram for explanation of an utterance section.

### DESCRIPTION OF EMBODIMENTS

Hereinafter, description will be made as to embodiments of the present invention. Note that in drawings for use in the following description, configuration units having the same function or steps of performing the same processing are denoted with the same reference sign, and redundant description is omitted.

### <Point of First Embodiment>

There is a method of using utterance corresponding to a predetermined word (a keyword) as a trigger for voice recognition start in a case of performing voice recognition. In the present embodiment, a sound volume of an audio signal of a target of the voice recognition is controlled by using a sound volume of an utterance section of this keyword. The utterance corresponding to the keyword and utterance that is a target of the voice recognition are usually the utterance by the same person, and hence it is considered that sound volumes of the utterances have a correlation. That is, if an utterance sound volume of the keyword is small, an utterance sound volume of the target of the voice recognition is very likely to be also small, and if the utterance sound volume of the keyword is large, the utterance sound volume of the target of the voice recognition is very likely to be also large. By use of this likeliness, a sound volume of the keyword to be uttered prior to the utterance of the target of the voice recognition is estimated, a gain is set from an estimated value, and the sound volume is controlled prior to the utterance of the target of the voice recognition.

### First Embodiment

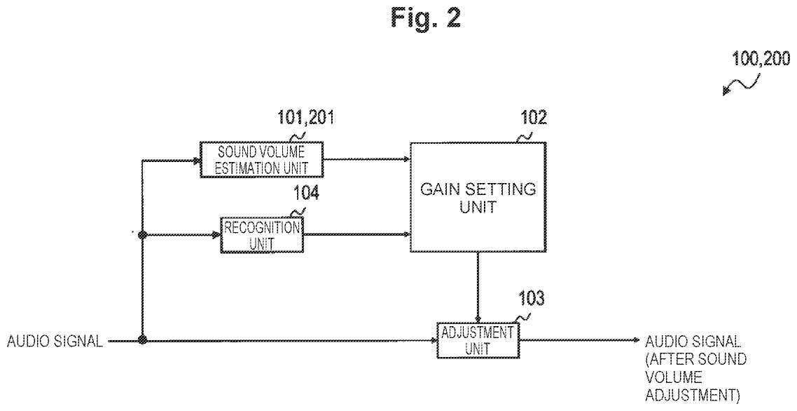

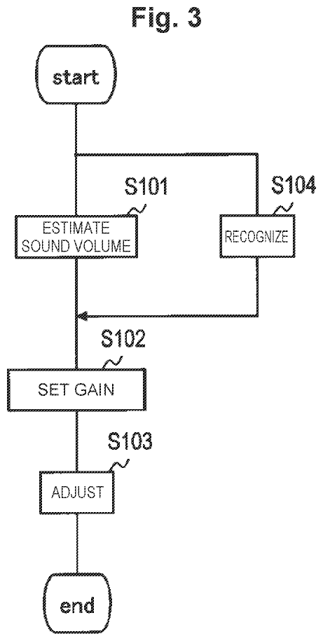

FIG. 2 shows a functional block diagram of a volume control apparatus 100 according to a first embodiment, and FIG. 3 shows a corresponding processing flow.

The volume control apparatus 100 includes a sound volume estimation unit 101, a recognition unit 104, a gain setting unit 102, and an adjustment unit 103.

An audio signal is inputted to the volume control apparatus 100, and the apparatus then controls a sound volume of the audio signal, and outputs the controlled audio signal. Note that examples of the audio signal include at least an audio signal corresponding to a predetermined voice command (the above described keyword) for use in starting voice recognition, and an audio signal of a target of the voice recognition.

The volume control apparatus 100 is, for example, a special device having a configuration where a special program is read into a known or designated computer including a central processing unit (CPU), a main memory (a random access memory (RAM)) and others. The volume control apparatus 100 executes each processing, for example, under control of the central processing unit. Data inputted to the volume control apparatus 100 and data obtained in each processing are stored, for example, in the main memory, and the data stored in the main memory is read to the central processing unit as required, for use in another processing. At least some of respective processing units of the volume control apparatus 100 may be composed of hardware such as an integrated circuit. Each storage unit provided in the volume control apparatus 100 may be composed of the main memory, such as the random access memory (RAM), or middleware such as a relational database or a key value store. However, each storage unit does not necessarily have to be provided in the volume control apparatus 100, and the storage unit may be composed of an auxiliary memory including a hard disk, an optical disk, or a semiconductor memory element such as a flash memory, and provided outside the volume control apparatus 100.

Hereinafter, description will be made as to the respective units.

### <Recognition Unit 104>

An audio signal is inputted to the recognition unit 104, to recognize a keyword included in the audio signal (S104). For example, the recognition unit 104 detects whether the keyword is included in the audio signal, and outputs a control signal to the gain setting unit 102 in a case where the keyword is included. Note that any technology may be used as a keyword detection technology. For example, the voice recognition may be performed for the audio signal by recognizing whether the keyword is included in a text of recognition result, or by recognizing similarity between a waveform of the audio signal and a waveform of the keyword which is obtained in advance and a magnitude relation in threshold.

### <Sound Volume Estimation Unit 101>

The audio signal is inputted to the sound volume estimation unit 101, and the unit estimates a sound volume of input voice (S101), and outputs an estimated value. Note that the sound volume to be estimated here is a sound volume of an audio signal related to the keyword. Consequently, after the recognition unit 104 recognizes the keyword, the sound volume estimation unit 101 may stop the sound volume estimation (S101) until corresponding voice recognition processing ends. In this case, the sound volume estimation unit 101 is configured to receive the control signal from the recognition unit 104. Then, upon receiving the control signal, the sound volume estimation unit 101 stops the estimation of the sound volume.

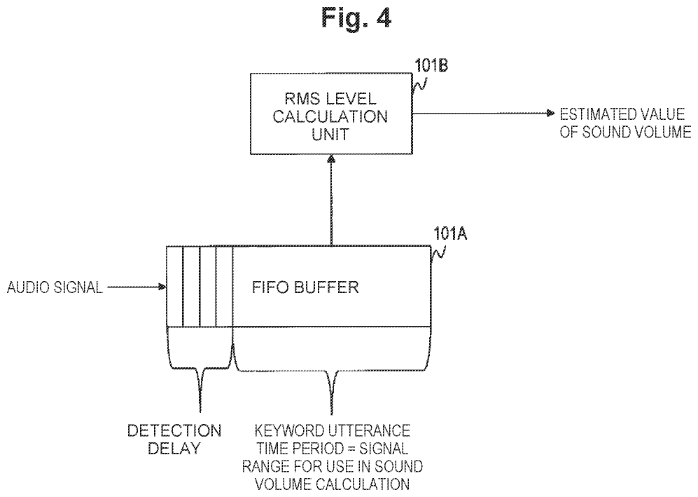

FIG. 4 shows an example of a functional block diagram of the sound volume estimation unit 101. In this example, the sound volume estimation unit 101 includes a FIFO buffer 101A and an RMS level calculation unit 101B.

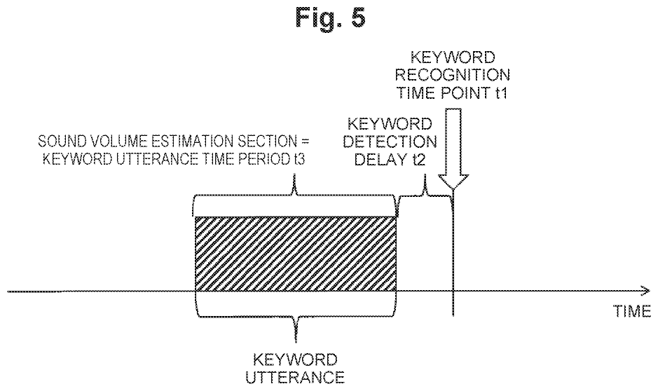

As shown in FIG. 5, a time period required for recognition of the keyword (hereinafter, also referred to as detection delay) is present, and hence a keyword utterance time period is present from past by the detection delay from a keyword recognition time point to past by the keyword utterance time period. It is necessary to estimate a sound volume of this section. For example, it is necessary to estimate a sound volume of a time section from a time point t1−t2−t3 to a time point t1−t2, in which t1 is the keyword recognition time point, t2 is the detection delay, and t3 is the keyword utterance time period. Consequently, an audio signal is inputted to the FIFO buffer 101A, and the buffer accumulates audio signals for a time period in which the keyword utterance time period t3 and the keyword detection delay t2 are added up, on a first-in first-out basis. As the keyword utterance time period t3 and the keyword detection delay t2, a standard utterance time period and a standard keyword detection delay are given as fixed values in advance. Alternatively, if it is possible to detect which section includes the keyword utterance in keyword detection processing, the keyword utterance time period t3 and the keyword detection delay t2 that are obtainable in the keyword detection processing may be successively changed for use. In this case, a FIFO buffer length is set to a maximum value of an assumed added value of the keyword utterance time period t3 and the keyword detection delay t2.

The RMS level calculation unit 101B takes out the audio signals for the standard keyword utterance time period from the oldest audio signal among the audio signals accumulated in the FIFO buffer 101A, calculates a root mean square (RMS) level, and outputs this calculated value as an estimated value of the sound volume. For example, the audio signal at time point t is X(t), and then the RMS level calculation unit 101B takes out the audio signals X(t1−t2−t3), X(t1−t2−t3+1), . . . , X(t1−t2), and calculates the root mean square (RMS) level.

### <Gain Setting Unit 102>

The estimated value of the sound volume is inputted to the gain setting unit 102. Then, the gain setting unit 102 holds the estimated value of the sound volume of the audio signal related to the keyword corresponding to the control signal, when the keyword is recognized, that is, when the control signal is received from the recognition unit 104. Then, the gain setting unit 102 sets a gain for the audio signal X of the target of the voice recognition, by use of this estimated value (S102), and the unit outputs the gain. For example, a sound volume optimum for the voice recognition (hereinafter, also referred to as the optimum sound volume) is set in advance, and the gain setting unit 102 sets, as the gain, a value obtained by dividing the optimum sound volume by a held estimated value.

### <Adjustment Unit 103>

When the audio signal and set gain are inputted to the adjustment unit 103, the unit adjusts the sound volume of the audio signal X of the target of the voice recognition of the voice uttered by a user, by use of the set gain (S103), and outputs the adjusted audio signal. For example, the inputted audio signal is multiplied by the set gain to adjust the sound volume.

### <Effect>

According to the above configuration, the volume control apparatus 100 sets the gain based on the keyword prior to the input of the audio signal of the target of the voice recognition, so that the sound volume can be appropriately controlled even immediately after start of utterance. The controlled audio signal is subjected to the voice recognition processing, so that voice recognition accuracy can be increased even immediately after the start of the utterance.

### <Modification>

In the present embodiment, the RMS level calculation unit 101B usually obtains the RMS level of the audio signals for a standard keyword utterance time period as the estimated value of the sound volume. Then, at a timing of receiving the control signal, the gain setting unit 102 sets the gain for the audio signal X of the target of the voice recognition, by use of the estimated value of the sound volume of the audio signal related to the keyword corresponding to the control signal. Alternatively, the gain may be set by the following method. In the method, the RMS level calculation unit 101B receives a control signal, and at a timing of receiving the control signal, the RMS level calculation unit takes out the audio signals for the standard keyword utterance time period from the oldest audio signal among the audio signals accumulated in the FIFO buffer 101A. Then, the RMS level calculation unit 101B obtains the RMS level of the audio signals for the standard keyword utterance time period as the estimated value of the sound volume. Afterward, at a timing of receiving the estimated value of the sound volume, the gain setting unit 102 sets the gain for the audio signal X of the target of the voice recognition. According to this configuration, a number of processing times to obtain the RMS level can be decreased.

### Second Embodiment

Parts different from those of the first embodiment will be mainly described.

The sound volume estimation unit 101 of the first embodiment obtains the RMS level of the standard keyword utterance time period, but in a case where there is an error between the standard keyword utterance time period and an actual keyword utterance time period, the sound volume estimation unit 101 cannot exactly estimate a sound volume of a keyword. To solve this problem, in the present embodiment, a sound volume estimation method is employed which is not influenced by the actual keyword utterance time period.

A volume control apparatus 200 according to the present embodiment includes a sound volume estimation unit 201, a recognition unit 104, a gain setting unit 102, and an adjustment unit 103 (see FIG. 2).

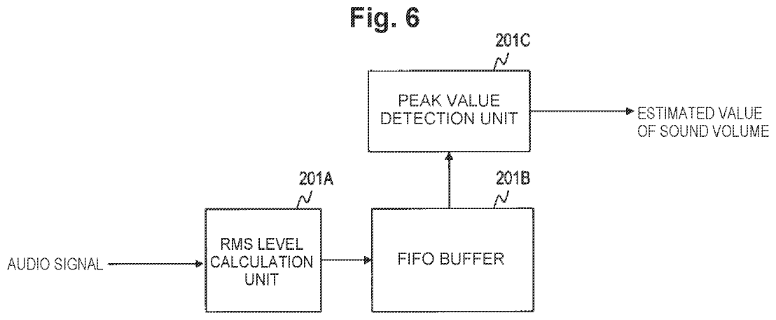

FIG. 6 shows an example of a functional block diagram of the sound volume estimation unit 201. In this example, the sound volume estimation unit 201 includes an RMS level calculation unit 201A, a FIFO buffer 201B, and a peak value detection unit 201C.

When an audio signal is inputted to the RMS level calculation unit 201A, the unit calculates an RMS level with a window length from about several tens of milliseconds to about several hundreds of milliseconds, and outputs the level.

The RMS level is inputted to the FIFO buffer 201B, and the unit accumulates RMS levels for a time period in which a standard keyword utterance time period and a keyword detection delay are added up, on a first-in first-out basis.

The peak value detection unit 201C takes out the accumulated RMS levels from the FIFO buffer 201B, detects a peak value, and outputs the peak value as an estimated value of the sound volume.

### <Effect>

According to such a configuration, an effect similar to that of the first embodiment can be obtained. Furthermore, even in a case where there is an error between the standard keyword utterance time period and an actual keyword utterance time period, the sound volume can be estimated without being influenced by the error.

### Third Embodiment

Parts different from those of the first embodiment will be mainly described.

In the present embodiment, instead of recognizing a keyword, a predetermined operation to be performed in starting voice recognition is recognized, and the voice recognition is started. Examples of the predetermined operation include processing of depressing a button provided in a steering wheel of an automobile, and processing of touching a touch panel such as an operation panel of the automobile. There are not any special restrictions on an audio signal of a target of the voice recognition. It is considered that an example of the audio signal is an audio signal corresponding to a voice command with which a user (e.g., a driver) orders execution of car navigation setting, phone calling, music playing, window opening/closing or the like.

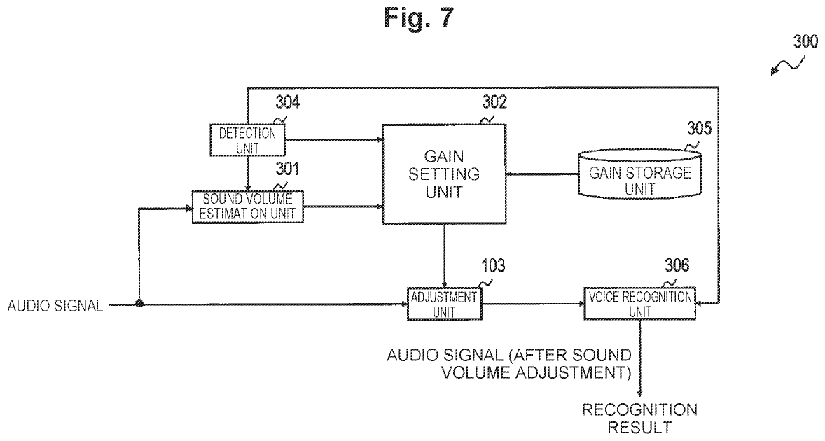

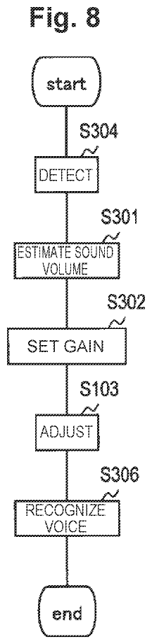

FIG. 7 shows a functional block diagram of a volume control apparatus 300 according to a first embodiment, and FIG. 8 shows an associated processing flow.

The volume control apparatus 300 includes a sound volume estimation unit 301, a detection unit 304, a gain setting unit 302, an adjustment unit 103, a gain storage unit 305, and a voice recognition unit 306.

When an audio signal is inputted to the volume control apparatus 300, the apparatus controls a sound volume of an audio signal, subjects the controlled audio signal to voice recognition, and outputs the recognition result.

### <Detection Unit 304>

The detection unit 304 detects a predetermined operation to be performed in starting the voice recognition (S304), and outputs a control signal. For example, the detection unit 304 comprises a button, a touch panel or the like. For example, the control signal is a signal that indicates “1” in a case where the predetermined operation is performed, and indicates “0” in another case. Here, examples of the predetermined operation include processing of depressing the button provided in a steering wheel of an automobile, and processing of touching the touch panel such as an operation panel of the automobile. The detection unit 304 detects the predetermined operation, and outputs the control signal indicating start of the voice recognition to the sound volume estimation unit 301, the gain setting unit 302 and the voice recognition unit 306.

### <Sound Volume Estimation Unit 301>

When an audio signal is inputted, and the control signal indicating the start of the voice recognition is received, the sound volume estimation unit 301 estimates the sound volume of input voice (S301), and outputs an estimated value.

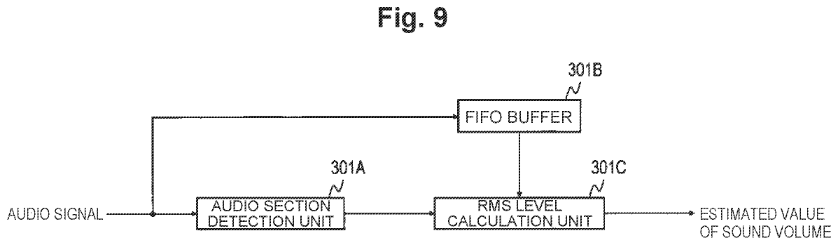

FIG. 9 shows an example of a functional block diagram of the sound volume estimation unit 301. In this example, the sound volume estimation unit 301 includes an audio section detection unit 301A, a FIFO buffer 301B, and an RMS level calculation unit 301C.

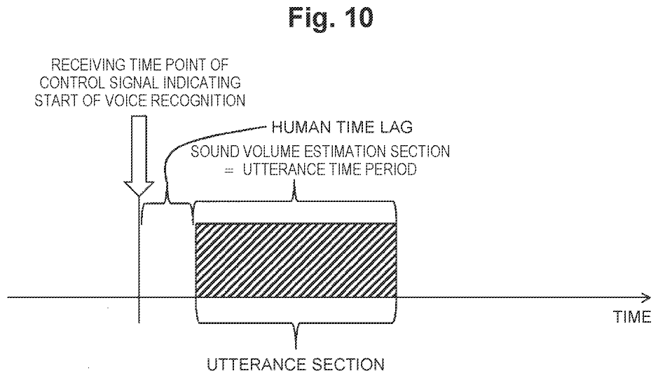

As shown in FIG. 10, in general, when a user performs a predetermined operation to be performed in starting the voice recognition, a time lag is generated until utterance of a target of voice recognition is actually performed. Furthermore, a length of the utterance of the target of the voice recognition is not determined. Therefore, an audio section is detected prior to estimation of a sound volume.

When the audio signal is inputted, and a control signal indicating start of the voice recognition is received, the audio section detection unit 301A detects the audio section included in the audio signal, and outputs information on the audio section. Note that any technology may be used as an audio section detection technology. Examples of the information on the audio section include information of a start time point and end time point of the audio section, information of the start time point of the audio section and a continuation length of the audio section, and any other information that shows the audio section.

The audio signal is inputted to the FIFO buffer 301B, and the unit accumulates the audio signals for a maximum time period in which the utterance of the target of the voice recognition is assumed, on a first-in first-out basis.

The RMS level calculation unit 301C receives the information on the audio section, takes out the audio signal corresponding to the audio section from the FIFO buffer 301B, calculates an RMS level of the audio section, and outputs the level as an estimated value of the sound volume.

### <Gain Setting Unit 302 and Gain Storage Unit 305>

The estimated value of the sound volume is inputted to the gain setting unit 302, and the unit sets a gain for an audio signal X of the target of the voice recognition, by use of the estimated value of the sound volume (S302), and the unit stores the gain in the gain storage unit 305. For example, an optimum sound volume for the voice recognition is set in advance, and the gain setting unit 302 sets, as a gain g(n), a value obtained by dividing the optimum sound volume by the estimated value estimated by the sound volume estimation unit 301. Here, the estimated value estimated by the sound volume estimation unit 301 is an estimated value of a sound volume of an (n−1)-th audio signal X(n−1).

In a case where an estimated value of a sound volume at a time of prior voice recognition is stored in the gain storage unit 305, the gain setting unit 302 takes out the estimated value from the gain storage unit 305, and outputs the value to the adjustment unit 103. That is, in this case, the gain setting unit 302 sets the gain g(n) for the n-th audio signal X(n) of the target of the voice recognition of the voice uttered by the user, by use of the (n−1)-th audio signal X(n−1) of the target of the voice recognition of the voice uttered by the user.

In a case where no estimated value of the sound volume at the time of the prior voice recognition is stored in the gain storage unit 305 (in a case of n=1), the gain setting unit 302 sets the gain g(n) for the audio signal X(n) of the target of the voice recognition, by use of the estimated value of the sound volume corresponding to the n-th audio signal X(n) of the target of the voice recognition of the voice uttered by the user, and the unit outputs the gain to the adjustment unit 103.

Note that when the audio signal and set gain are inputted to the adjustment unit 103, the unit adjusts the sound volume of the n-th audio signal X(n) of the target of the voice recognition of the voice uttered by the user, by use of the set gain g(n) (S103), and the unit outputs the adjusted audio signal.

According to such a configuration, the gain g(n) is set by use of the (n−1)-th audio signal X(n−1) in n≥2, and delay in the estimation of the sound volume can be prevented.

### <Voice Recognition Unit 306>

When the adjusted audio signal is inputted and the control signal indicating the start of the voice recognition is received, the voice recognition unit 306 recognizes the voice from the audio signal X(n) having the sound volume adjusted (S306), and outputs the recognition result.

### <Effect>

According to such a configuration, an effect similar to that of the first embodiment can be obtained.

### <Another Modification>

The present invention is not limited to the above embodiments and modification. For example, the above described various types of processing may not only be executed in chronological order in accordance with the description but also be executed in parallel or individually in accordance with processing ability of a processing execution apparatus or as required. Additionally, the present invention can be suitably changed without departing from the scope of the present invention.

### <Program and Recording Medium>

Furthermore, various types of processing functions in the respective apparatuses described in the above embodiments and modifications may be achieved by a computer. In this case, a processing content of the function that each apparatus has to have is described by a program. Then, this program is executed by the computer, and various processing functions in the above respective apparatuses can be achieved on the computer.

The program in which this processing content is described can be recorded in a computer readable recording medium in advance. Examples of the computer readable recording medium may include a magnetic recording device, an optical disk, a photomagnetic recording medium, a semiconductor memory, and any other medium.

Furthermore, this program is distributed, for example, by sale, transfer, loan or the like of a portable recording medium such as a DVD or a CD-ROM in which the program is recorded. Alternatively, this program may be distributed by storing this program in a storage device of a server computer in advance, and forwarding the program from the server computer to another computer via a network.

Such a program execution computer, for example, first stores, once in its own storage unit, the program recorded in the portable recording medium or the program forwarded from the server computer. Then, at a time of execution of processing, this computer reads the program stored in its own storage unit, and executes the processing in accordance with the read program. Alternatively, as another embodiment of this program, the computer may read the program directly from the portable recording medium, and execute processing in accordance with the program. Furthermore, every time the program is forwarded from the server computer to this computer, the computer may sequentially execute processing in accordance with the received program. Alternatively, the above described processing may be configured to be executed by a so-called application service provider (ASP) type of service in which any program is not forwarded from the server computer to this computer and in which a processing function is achieved only by execution instruction and result acquisition. Note that the program includes information that is for use in processing by an electronic computer and that is equivalent to the program (e.g., data that is not a direct instruction to the computer and that has properties prescribing computer processing).

Furthermore, a predetermined program is executed on the computer, to constitute each apparatus, but at least some of these processing contents may be achieved in a hardware manner.

1. A volume control apparatus comprising:
processing circuitry configured to:
recognize a predetermined voice command for use in starting voice recognition;
execute a gain setting processing in which the processing circuitry sets a gain for an audio signal X of a target of the voice recognition, by use of an audio signal related to the predetermined voice command uttered by a user; and
adjust a sound volume of the audio signal X, by use of the gain.

2. A volume control apparatus comprising:
processing circuitry configured to:
detect a predetermined operation to be performed in starting voice recognition;
execute a gain setting processing in which the processing circuitry sets a gain g(n) for an n-th audio signal X(n) of a target of voice recognition of a voice uttered by a user, by use of an (n−1)-th audio signal X(n−1) of the target of the voice recognition of the voice uttered by the user;
adjust a sound volume of the audio signal X(n), by use of the gain g(n), in a case where the predetermined operation is detected; and
recognize the voice of the audio signal X(n) having the sound volume adjusted, in the case where the predetermined operation is detected.

3. The volume control apparatus according to claim 1, wherein
the processing circuitry is configured to estimate a sound volume of the audio signal related to the predetermined voice command, and
in the gain setting processing the processing circuitry sets, as the gain, a value obtained by dividing an optimum sound volume for the voice recognition by an estimated value of the sound volume of the audio signal related to the predetermined voice command.

4. The volume control apparatus according to claim 2, wherein
the processing circuitry is configured to estimate a sound volume of the audio signal X(n−1), and
in the gain setting processing the processing circuitry sets, as the gain g(n), a value obtained by dividing an optimum sound volume for the voice recognition by an estimated value of the sound volume of the audio signal X(n−1).

5. A volume control method, implemented by a volume control apparatus that includes processing circuitry, comprising:
a recognition step in which the processing circuitry recognizes a predetermined voice command for use in starting voice recognition,
a gain setting step in which the processing circuitry sets a gain for an audio signal X of a target of the voice recognition, by use of an audio signal related to the predetermined voice command uttered by a user, and
an adjustment step in which the processing circuitry adjusts a sound volume of the audio signal X, by use of the gain.

6. A volume control method, implemented by a volume control apparatus that includes processing circuitry, comprising:
a detection step in which the processing circuitry detects a predetermined operation to be performed in starting voice recognition,
a gain setting step in which the processing circuitry sets a gain g(n) for an n-th audio signal X(n) of a target of voice recognition of a voice uttered by a user, by use of an (n−1)-th audio signal X(n−1) of the target of the voice recognition of the voice uttered by the user,
an adjustment step in which the processing circuitry adjusts a sound volume of the audio signal X(n), by use of the gain g(n), in a case where the predetermined operation is detected, and
a voice recognition step in which the processing circuitry recognizes the voice of the audio signal X(n) having the sound volume adjusted, in the case where the predetermined operation is detected.

7. A program non-transitory computer-readable recording medium that records a that causes a computer to function as the volume control apparatus according to claim 1 or 2.
